(19) United States
(12) Patent Application Publication
(10) Pub. No.: US 2024/0128308 A1
(43) Pub. Date: Apr. 18, 2024

(54) METHOD FOR FABRICATING A FERROELECTRIC DEVICE

(71) Applicants: Tokyo Electron Limited, Tokyo (JP); Ferroelectric Memory GmbH, Dresden (DE)

(72) Inventors: Dina Triyoso, Albany, NY (US); Robert Clark, Albany, NY (US); Kandabara Tapily, Albany, NY (US); Tony Schenk, Dresden (DE); Alireza Kashir, Dresden (DE); Stefan Ferdinand Mueller, Dresden (DE)

(21) Appl. No.: 18/487,502

(22) Filed: Oct. 16, 2023

Related U.S. Application Data
(60) Provisional application No. 63/379,938, filed on Oct. 18, 2022.

(51) Int. Cl. H10B 53/00; H01L 21/02; H01L 21/283; H01L 21/321

(52) U.S. Cl. CPC H01L 28/40; H01L 21/02181; H01L 21/02189; H01L 21/02194; H01L 21/0228; H01L 21/283; H01L 21/321; H10B 53/00

(57) ABSTRACT

A method for fabricating a ferroelectric device includes providing a lower electrode layer on a substrate, forming a retention enhancement layer by oxidizing a surface of the lower electrode layer using a gas phase oxidation process, and depositing a ferroelectric high-k metal oxide layer over the retention enhancement layer on the lower electrode layer using a vapor deposition process. The retention enhancement layer on the lower electrode layer increases the retention performance and reliability of the ferroelectric device.

### CROSS-REFERENCE TO RELATED APPLICATIONS

This application is related to and claims priority to U.S. Provisional Patent Application Ser. No. 63/379,938 filed on Oct. 18, 2022, the entire contents of which are herein incorporated by reference.

### FIELD OF THE INVENTION

The present invention relates to semiconductor processing and semiconductor devices, and more particularly, to structures of dielectric films on a substrate, including ferroelectric high-k films that may be used as capacitors and memory cells in semiconductor devices.

### BACKGROUND OF THE INVENTION

Dielectric materials that are ferroelectric (FE) and antiferroelectric (AFE) are types of dielectric materials that can, for example, be used for CMOS-related applications, including field-effect transistor (FET) devices and dynamic random-access memory (DRAM) devices. Resistive RAM (ReRAM) devices are a class of storage memory devices that have received much attention due to the potential payout toward high-density/low-cost/low-energy non-volatile memories. A requirement for film stacks containing these dielectric materials for data storage includes long retention times and high switching speeds.

### SUMMARY OF THE INVENTION

Embodiments of the invention provide a method for fabricating a ferroelectric device. The ferroelectric device can include a ferroelectric material that is integrated with metal electrodes in a film stack. The disclosed method includes forming a retention enhancement layer on a surface of a lower electrode layer using a gas phase oxidation process, where the resulting ferroelectric device has improved retention performance and high reliability.

According to one embodiment, the method includes providing a lower electrode layer on a substrate, forming a retention enhancement layer by oxidizing a surface of the lower electrode layer using a gas phase oxidation process, and depositing a ferroelectric high-k metal oxide layer over the retention enhancement layer using a vapor deposition process.

According to another embodiment, the method includes providing a lower electrode layer on a substrate, forming a retention enhancement layer by oxidizing a surface of the lower electrode layer using ozone, depositing a ferroelectric hafnium zirconium oxide (HfZrOₓ) layer in direct physical contact with the retention enhancement layer using a vapor deposition process, and depositing an upper electrode layer above the ferroelectric hafnium zirconium oxide layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a process flow diagram for processing a substrate according to an embodiment of the invention;

FIGS. 2A-2D schematically show through cross-sectional views a method of processing a substrate according to an embodiment of the invention; and

FIGS. 3A and 3B show electrical test results for characterizing retention performance for ferroelectric film capacitors according to embodiments of the invention.

### DETAILED DESCRIPTION OF SEVERAL EMBODIMENTS

Embodiments of the invention provide a method for fabricating a ferroelectric device that includes a ferroelectric material integrated with a retention enhancement layer and metal electrodes in a film stack. According to one embodiment, the method includes providing a lower electrode layer on a substrate, forming a retention enhancement layer on the lower electrode layer using a gas phase oxidation process, and depositing a ferroelectric high-k metal oxide layer over the retention enhancement layer using a vapor deposition process. The formation of the retention enhancement layer on the lower electrode layer results in improved retention performance and good reliability of the resulting ferroelectric memory device.

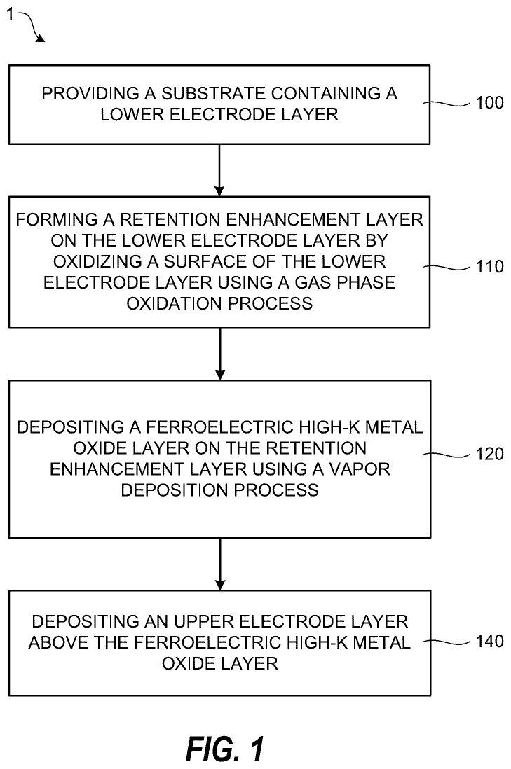

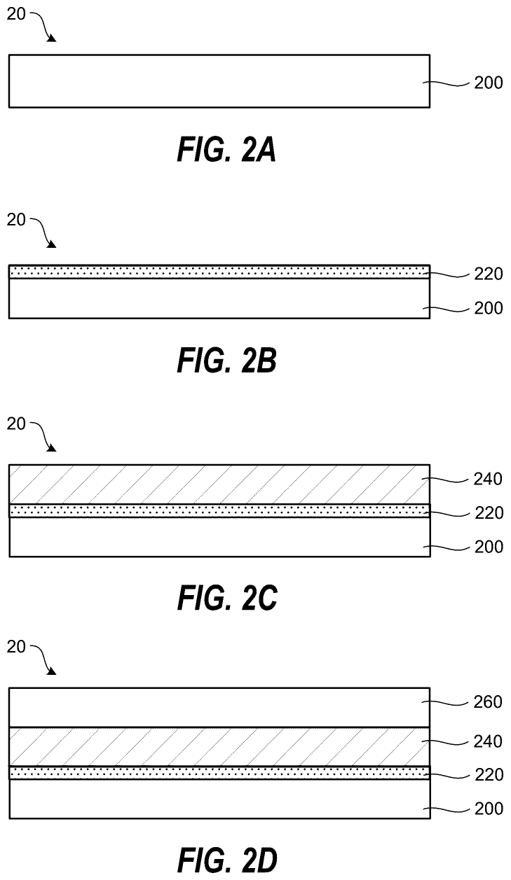

According to one embodiment, schematically shown in FIGS. 1 and 2A-2D, a method in flowchart 1 includes, in 100, providing in a process chamber a substrate 20 containing a lower electrode layer 200. The lower electrode layer 200 may contain a metal layer or a laminate of different metal layers. According to one embodiment, the lower electrode layer 200 includes a titanium (Ti) metal layer, a tungsten (W) metal layer, or a laminate thereof. The laminate can include Ti/W or W/Ti.

The method further includes, in 110, forming a retention enhancement layer 220 on the lower electrode layer 200 using a gas phase oxidation process. This is schematically shown in FIG. 2B. According to one embodiment, the retention enhancement layer 220 can include an oxidized surface of the lower electrode layer 200. In one example, forming the oxidized surface includes exposing the lower electrode layer 200 to gas phase ozone (O₃), where the gas phase exposure oxidizes a top surface of a metal layer of the lower electrode layer 200. According to another embodiment, forming the oxidized surface includes exposing the lower electrode layer 200 to plasma-excited O₂ gas.

According an embodiment, forming the retention enhancement layer 220 incorporates oxygen atoms into a surface of the lower electrode layer 200 and the oxygen incorporation does not significantly increase the thickness of the lower electrode layer 200. In other words, the combined thickness of the retention enhancement layer 220 and the lower electrode layer 200 in FIG. 2B is not significantly greater than the thickness of the lower electrode layer 200 in FIG. 2A. This is advantageous where there are strict limitations on the device height, and where a significant increase in the stack height could alter the electronic and material properties of the device.

According to one embodiment, forming the oxidized surface includes: a) exposing the substrate 20 to gas phase ozone, b) purging the process chamber with an inert gas, and c) repeating steps a) and b) at least once. In one example, ozone may be flowed for about 5 seconds in step a), and the inert gas may be flowed for about 10 seconds in step b).

According to one embodiment, forming the oxidized surface includes performing plasma oxidation on the lower electrode layer 200. In one example, the gas phase oxidation process includes a gas exposure time between about 30 seconds and about 30 minutes to a plasma-excited oxygen-containing gas (e.g., O₂).

According to one embodiment, performing the plasma oxidation includes using a microwave excitation source to excite O₂ gas, and exposing the substrate 20 to the excited O₂ gas.

According to one embodiment, performing the plasma oxidation includes using a remote plasma excitation source to excite O₂ gas, and exposing the substrate 20 to the plasma-excited O₂ gas.

According to one embodiment, forming the oxidized surface on the lower electrode layer 200 further includes heating the substrate 20 to a temperature between about room temperature and about 500° C. According to one embodiment, forming the retention enhancement layer 220 further includes heating the substrate 20 to a temperature between about 250° C. and about 300° C.

The method further includes, in 120, depositing a ferroelectric high-k metal oxide layer 240 over the retention enhancement layer 220 using a vapor deposition process. According to one embodiment, the ferroelectric high-k metal oxide layer 240 is in direct physical contact with the retention enhancement layer. This is schematically shown in FIG. 2C.

According to some embodiments, the ferroelectric high-k metal oxide layer 240 includes a ferroelectric high dielectric constant (high-k) material with a dielectric constant greater than that of SiO₂ (k˜4). In some embodiments, the vapor deposition process can include chemical vapor deposition (CVD) or atomic layer deposition (ALD). In the example of ALD, the process can include cycles of alternating saturating gaseous exposures of a metal-containing precursor and an oxidizer, where each cycle includes one exposure of the metal-containing precursor, followed by one exposure of the oxidizer. Each cycle deposits one atomic layer or less of the metal oxide, and the number of cycles may selected in order to accurately control the film thickness. Steric hindrance of ligands in the metal-containing precursor and the oxidizer, and a limited number of bonding sites, can limit the chemisorption on the substrate surface, and therefore the film growth per cycle can remain at less than one atomic layer.

In one embodiment, depositing the ferroelectric high-k metal oxide layer 240 includes, sequentially first, exposing the substrate 20 to a metal-containing precursor vapor, and, sequentially second, exposing the substrate 20 to an oxygen-containing gas.

According to some embodiments, the ferroelectric high-k metal oxide layer 240 can contain zirconium oxide (ZrO₂), hafnium oxide (HfO₂), or laminates or mixtures thereof. In one example, the ferroelectric high-k metal oxide layer 240 can be hafnium zirconium oxide (HfZrOₓ). The HfO₂ or ZrO₂ may be doped with aluminum (Al), gadolinium (Gd), lanthanium (La), silicon (Si), strontium (Sr), or yttrium (Y) dopants.

In one example, a ferroelectric high-k metal oxide layer 240 containing ZrO₂ may be deposited by ALD using cycles of alternating gaseous exposures of a zirconium-containing precursor and an oxidizer. In another example, a ferroelectric high-k metal oxide layer 240 containing a mixture of ZrO₂ and HfO₂ may be deposited by ALD using cycles of alternating gaseous exposures of a zirconium-containing precursor, and oxidizer, a hafnium-containing precursor, and an oxidizer. In yet another example, a ferroelectric high-k metal oxide layer 240 containing doped HfO₂ may be deposited by ALD using cycles of alternating gaseous exposures of a hafnium-containing precursor, a dopant gas, and an oxidizer. The dopant concentration can, for example, be between about 0.1 atomic % and about 20 atomic %, between about 0.1 atomic % and about 10 atomic %, or between about 0.1 atomic % and about 1 atomic %.

Embodiments of the invention may utilize a wide variety of zirconium (Zr) and hafnium (Hf) precursors for the vapor phase deposition. For example, representative examples include: Zr(O^{t}Bu)₄ (zirconium tert-butoxide, ZTB), Zr(NEt₂)₄ (tetrakis(diethylamido)zirconium, TDEAZ), Zr(NMeEt)₄ (tetrakis(ethylmethylamido)zirconium, TEMAZ), Zr(NMe₂)₄ (tetrakis(dimethylamido)zirconium, TDMAZ), Hf(OtBu)₄ (hafnium tert-butoxide, HTB), Hf(NEt₂)₄ (tetrakis(diethylamido)hafnium, TDEAH), Hf(NEtMe)₄ (tetrakis(ethylmethylamido)hafnium, TEMAH), and Hf(NMe₂)₄ (tetrakis(dimethylamido)hafnium, TDMAH). In some examples, tris(dimethylaminocyclopentadienylhafnium (HfCp(NMe₂)₃) available from Air Liquide as HyALD™ may be used as a hafnium precursor and tris(dimethylaminocyclopentadienylzirconinum (ZrCp(NMe₂)₃) available from Air Liquide as ZyALD™ may be used as a zirconium precursor. The oxidizer may include an oxygen-containing gas, including plasma-excited O₂, water (H₂O), or ozone (O₃).

The Al, Gd, La, Si, Sr, and Y dopants may be provided using any dopant gases that have sufficient reactivity, thermal stability, and volatility.

Examples of Al precursors include Al₂Me₆, Al₂Et₆, [Al(O(sBu))₃]4, Al(CH₃COCHCOCH₃)₃, AlBr₃, AlI₃, Al(O(iPr))₃, [Al(NMe₂)₃]₂, Al(iBu)₂Cl, Al(iBu)₃, Al(iBu)₂H, AlEt₂Cl, Et₃Al₂(O(sBu))₃, and Al(THD)₃.

Examples of Gd precursors include Gd(N(SiMe₃)₂)₃, ((iPr)Cp)₃Gd, Cp₃Gd, Gd(THD)₃, GdPOCCH(C₂H₅)C₄H₉]₃, Gd(O(iPr))₃, and Gd(acac)₃.

Examples of La precursors include La(N(SiMe₃)₂)₃, La(N(iPr)₂)₃, La(N(tBu)SiMe₃)₃, La(TMPD)₃, ((iPr)Cp)₃La, Cp₃La, Cp₃La(NCCH₃)₂, La(Me₂NC₂H₄Cp)₃, La(THD)₃, La[OCCH(C₂H₅)C₄H₉]₃, La(C₁₁H₁₉O₂)₃CH₃(OCH₂CH₂)₃OCH₃, La(C₁₁H₁₉O₂)₃·CH₃(OCH₂CH₂)₄OCH₃, La(O(iPr))₃, La(OEt)₃, La(acac)₃, La(((tBu)₂N)₂CMe)₃, La(((iPr)₂N)₂CMe)₃, La(((tBu)₂N)₂C(tBu))₃, La(((iPr)₂N)₂C(tBu))₃, and La(FOD)₃.

Examples of silicon precursors include silane (SiH₄), disilane (Si₂H₆), monochlorosilane (SiClH₃), dichlorosilane (SiH₂Cl₂), trichlorosilane (SiHCl₃), hexachlorodisilane (Si₂Cl₆), diethylsilane (Et₂SiH₂), and alkylaminosilane compounds. Examples of alkylaminosilane compounds include, but are not limited to, di-isopropylaminosilane (H₃Si(NPr₂)), bis(tert-butylamino)silane ((C₄H₉(H)N)₂SiH₂), tetrakis(dimethylamino)silane (Si(NMe₂)₄), tetrakis(ethylmethylamino)silane (Si(NEtMe)₄), tetrakis(diethylamino)silane (Si(NEt₂)₄), tris(dimethylamino)silane (HSi(NMe₂)₃), tris(ethylmethylamino)silane (HSi(NEtMe)₃), tris(diethylamino)silane (HSi(NEt₂)₃), and tris(dimethylhydrazino)silane (HSi(N(H)NMe₂)₃), bis(diethylamino)silane (H₂Si(NEt₂)₂), bis(di-isopropylamino)silane (H₂Si(NPr₂)₂), tris(isopropylamino)silane (HSi(NPr₂)₃), and (di-isopropylamino)silane (H₃Si(NPr₂).

Examples of Sr precursors include Bis(tert-butylacetamidinato)strontium (TBAASr), Sr-C, Sr-D, Sr(N(SiMe₃)₂)₂, Sr(THD)₂, Sr(THD)₂ (tetraglyme), Sr(iPr₄Cp)₂, Sr(iPr₃Cp)₂, and Sr(Me₅Cp)₂.

Examples of Y precursors include Y(N(SiMe₃)₂)₃, Y(N(iPr)₂)₃, ((iPr)Cp)₃Y, Cp₃Y, Y(THD)₃, Y[OOCCH(C₂H₅)C₄H₉]₃, Y(O(iPr))₃, Y(acac)₃, (C₅Me₅)₂Y, Y(hfac)₃, and Y(FOD)₃.

In the above precursors, as well as precursors set forth below, the following common abbreviations are used: Si: silicon; Me: methyl; Et: ethyl; iPr: isopropyl; nPr: n-propyl; Bu: butyl; nBu: n-butyl; sBu: sec-butyl; iBu: iso-butyl; tBu: tert-butyl; Cp: cyclopentadienyl; THD: 2,2,6,6-tetramethyl-3,5-heptanedionate; TMPD: 2,2,6,6-tetramethylpiperidide; acac: acetylacetonate; hfac: hexafluoroacetylacetonate; and FOD: 6,6,7,7,8,8,8-heptafluoro-2,2-dimethyl-3,5-octanedionate.

Following deposition of the ferroelectric high-k metal oxide layer 240, a heat-treating process may be performed on the substrate 20 using a predetermined substrate temperature and time period. The heat-treating organizes the atomic elements in the ferroelectric high-k metal oxide layer 240, reduces the film stress, and locks in the crystallographic orientation of the ferroelectric high-k metal oxide layer 240. The heat-treating may be performed at a substrate temperature of about 500° C. or lower, between about 200° C. and about 500° C., between about 200° C. and about 300° C., between about 300° C. and about 400° C., or between about 400° C. and about 500° C. In one example, the heat-treating may be performed in the same process chamber as the deposition of the ferroelectric high-k metal oxide layer 240. In another example, the heat-treating may be formed in a different process chamber than the deposition of the ferroelectric high-k metal oxide layer 240. The heat-treating may be performed under vacuum conditions in the presence of an inert gas, for example argon(Ar) or nitrogen (N 2).

Referring back to FIG. 1, the method further includes, in 140, depositing an upper electrode layer 260 above ferroelectric high-k metal oxide layer 240. According to one embodiment, the upper electrode layer is in direct physical contact with the ferroelectric high-k metal oxide layer 240. This is schematically shown in FIG. 2D. According to one embodiment, the upper electrode layer 260 includes a tungsten (W) metal layer.

According to one embodiment, a method is provided for fabricating a ferroelectric device, where the method includes providing a lower electrode layer on a substrate, forming a retention enhancement layer by oxidizing a surface on the lower electrode layer using ozone, depositing a ferroelectric hafnium zirconium oxide (HfZrOₓ) layer in direct physical contact with the retention enhancement layer using a vapor deposition process, and depositing an upper electrode layer above the ferroelectric hafnium zirconium oxide layer. The lower electrode layer can include a titanium (Ti) metal layer, a tungsten (W) metal layer, or a laminate thereof, and the upper electrode layer can include a tungsten (W) metal layer. In one example, the film stack can include a 10 nm W upper electrode layer, a 10 nm HfZrOₓ layer, and a 1.0 nm Ti/50 nm W lower electrode layer.

According to one embodiment, the steps of forming the retention enhancement layer using a gas phase oxidation process, and depositing a ferroelectric high-k metal oxide layer over the retention enhancement layer using a vapor deposition process, may be performed on the same processing tool without air exposure between the steps. The steps may be performed in the same process chamber or in different process chambers.

In one example, the process chamber may be configured to perform plasma exposure of a lower electrode layer to form a retention enhancement layer by gas phase oxidation. In another example, the process chamber may be configured to also perform atomic layer deposition (ALD) of a ferroelectric material over the retention enhancement layer. In another example, a first process chamber may be configured to perform surface oxidation of a lower electrode layer to form a retention enhancement layer by gas phase oxidation. Further, following the surface oxidation, the substrate may be transferred to a second process chamber that is configured to perform atomic layer deposition (ALD) of a ferroelectric material over the retention enhancement layer.

The exemplary film stack described in FIGS. 2A-2D may be used in MIM (Metal/Insulator/Metal) structures for 2D and 3D FeCAP (Ferroelectric capacitor) for embedded memory applications (e.g., FRAM, NVRAM, Flash, and DRAM), as well as a memory element for AI applications.

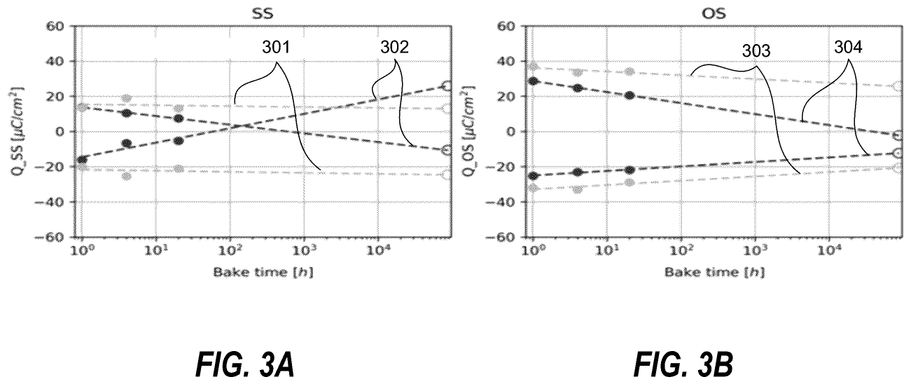

FIGS. 3A and 3B show electrical test results for characterizing retention performance for ferroelectric film capacitors, both same state performance (SS in FIG. 3A) and opposite state performance (OS in FIG. 3B). The test structures included film stacks containing Ti/W/HfZrOx/W layers. A first test structure was prepared where a retention enhancement layer was formed by oxidizing a surface of tungsten (W) metal (a lower electrode layer) using an ozone gas exposure. The ozone gas exposure was omitted for a second test structure.

The electrical tests included the steps of writing an original complementary data state into the first and second test structures after the test structures were initialized into an initial valid data state. The first and second test structures were then subjected to time and temperature stress. The original complementary data state from the first and second test structures was then read, and same state charge (Q_SS) information collected. An opposite complementary data state was then written in the first and second test structures. After a short time interval, the Opposite complementary data state from the first and second test structures was read to gather opposite state charge (Q_OS) information. The original complementary data state was then written into the first and second test structures. The first and second test structures were then subjected to further stress cycles, after which the same state and opposite state charge values were recorded.

Plots of the same state charge (Q_SS) versus log time are shown in FIG. 3A. The first test structure (fitted curves 301) showed improved retention performance over the temperature stress conditions (bake time) than the second test structure (fitted curves 302). Similarly, plots of the opposite state charge (Q_OS) versus log time are shown in FIG. 3B. The first test structure (fitted curves 303) showed improved retention performance over the temperature stress conditions (bake time) than the second test structure (fitted curves 304).

A plurality of embodiments for a ferroelectric device have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. It is therefore intended that the scope of the invention be limited not by this detailed description, but rather by the claims appended hereto.

What is claimed is:

1. A method for fabricating a ferroelectric device, the method comprising:
providing a lower electrode layer on a substrate;
forming a retention enhancement layer by oxidizing a surface of the lower electrode layer using a gas phase oxidation process; and
depositing a ferroelectric high-k metal oxide layer over the retention enhancement layer using a vapor deposition process.

2. The method of claim 1, wherein forming the retention enhancement layer includes exposing the lower electrode layer to ozone.

3. The method of claim 1, wherein forming the retention enhancement layer includes exposing the lower electrode layer to plasma-excited O₂ gas.

4. The method of claim 1, wherein forming the retention enhancement layer includes using a microwave excitation source to excite O₂ gas, and exposing the lower electrode layer to the plasma-excited O₂ gas.

6. The method of claim 4, wherein forming the retention enhancement layer using a remote plasma excitation source to excite O₂ gas, and exposing the lower electrode layer to the plasma-excited O₂ gas.

7. The method of claim 1, wherein forming the retention enhancement layer further includes heating the substrate to a temperature between about room temperature and about 500° C.

8. The method of claim 1, wherein forming the retention enhancement layer further includes heating the substrate to a temperature between about 250° C. and about 300° C.

9. The method of claim 1, wherein the ferroelectric high-k metal oxide layer is in direct physical contact with the retention enhancement layer.

10. The method of claim 1, further comprising depositing an upper electrode layer above the ferroelectric high-k metal oxide layer.

11. The method of claim 10, wherein the upper electrode layer is in direct physical contact with the ferroelectric high-k metal oxide layer.

12. The method of claim 10, wherein the upper electrode layer includes a tungsten (W) metal layer.

13. The method of claim 1, wherein the lower electrode layer includes a titanium (Ti) metal layer, a tungsten (W) metal layer, or a laminate thereof.

14. The method of claim 1, wherein the ferroelectric high-k metal oxide layer includes hafnium oxide (HfOₓ), zirconium oxide (ZrOₓ), or hafnium zirconium oxide (HfZrOₓ).

15. The method of claim 1, wherein depositing the ferroelectric high-k metal oxide layer includes exposing the substrate to a metal-containing precursor vapor, and exposing the substrate to an oxygen-containing gas.

16. A method for fabricating a ferroelectric device, the method comprising:
providing a lower electrode layer on a substrate;
forming a retention enhancement layer by oxidizing a surface of the lower electrode layer using ozone; and
depositing a ferroelectric hafnium zirconium oxide (HfZrOₓ) layer in direct physical contact with the retention enhancement layer using a vapor deposition process; and
depositing an upper electrode layer above the ferroelectric hafnium zirconium oxide layer.

17. The method of claim 16, wherein the lower electrode layer includes a titanium (Ti) metal layer, a tungsten (W) metal layer, or a laminate thereof, and the upper electrode layer includes a tungsten (W) metal layer.

18. A method for fabricating a ferroelectric device, the method comprising:
providing, in a first process chamber, a lower electrode layer on a substrate;
forming a retention enhancement layer by oxidizing a surface of the lower electrode layer using a gas phase oxidation process in the first process chamber;
transferring the substrate into a second process chamber; and
depositing a ferroelectric high-k metal oxide layer over the retention enhancement layer using a vapor deposition process in a second process chamber.

19. The method of claim 18, wherein the first process chamber is configured for performing surface oxidation of the lower electrode layer to form the retention enhancement layer, and wherein the second process chamber is configured to perform atomic layer deposition (ALD) of the ferroelectric high-k oxide layer.

20. The method of claim 18 wherein the ferroelectric high-k metal oxide layer includes hafnium oxide (HfOₓ), zirconium oxide (ZrOₓ), or hafnium zirconium oxide (HfZrOₓ).
